(19) United States
(12) Patent Application Publication
(10) Pub. No.: US 2025/0160029 A1
(43) Pub. Date: May 15, 2025

(54) SOLID-STATE IMAGING ELEMENT, MANUFACTURING METHOD, AND ELECTRONIC DEVICE

(71) Applicant: SONY SEMICONDUCTOR SOLUTIONS CORPORATION, KANAGAWA (JP)

(72) Inventor: SHOTA KITAMURA, KANAGAWA (JP)

(21) Appl. No.: 18/835,609

(22) PCT Filed: Feb. 2, 2023
(86) PCT No.: PCT/JP2023/003341

§ 371 Date: Aug. 2, 2024

(30) Foreign Application Priority Data
Feb. 14, 2022 (JP) 2022-020452

(51) Int. Cl. H10F 39/00

(52) U.S. Cl. CPC H10F 39/811; H10F 39/018; H10F 39/809

(57) ABSTRACT

The present disclosure relates to a solid-state imaging element, a manufacturing method, and an electronic device capable of achieving higher performance. In the solid-state imaging element, a second semiconductor substrate is bonded to a first semiconductor substrate provided with a photodiode and some pixel transistors for each pixel, the second semiconductor substrate being provided with pixel transistors other than the some pixel transistors constituting the pixel, an interlayer film is stacked on a surface of the second semiconductor substrate via an insulating film, the surface being opposite to a surface on a side to which the first semiconductor substrate is bonded, and a through electrode penetrating the second semiconductor substrate from the interlayer film side and electrically connected to the first semiconductor substrate is provided. The through electrode includes a lower electrode provided from substantially the same height as the surface of the second semiconductor substrate on the interlayer film side toward the second semiconductor substrate, and an upper electrode penetrating the interlayer film and connected to the lower electrode. The present technology can be applied to, for example, a back-illuminated CMOS image sensor having a stacked structure.

### TECHNICAL FIELD

The present disclosure relates to a solid-state imaging element, a manufacturing method, and an electronic device, and more particularly, to a solid-state imaging element, a manufacturing method, and an electronic device capable of achieving higher performance.

### BACKGROUND ART

Conventionally, in a solid-state imaging element such as a complementary metal oxide semiconductor (CMOS) image sensor, for example, a stacked structure in which a logic substrate provided with a logic circuit is bonded to a sensor substrate provided with a plurality of pixels via an interlayer insulating film is adopted.

Moreover, in recent years, a sensor substrate in which a photodiode and a pixel transistor constituting a pixel are formed on different substrates, for example, a sensor substrate having a structure in which a first semiconductor substrate provided with a photodiode and a transfer transistor and a second semiconductor substrate provided with an amplification transistor, a selection transistor, a reset transistor, and the like are bonded has been developed. In the sensor substrate having such a structure, the transfer transistor of the first semiconductor substrate is electrically connected to the second semiconductor substrate and the logic substrate by a through contact penetrating the second semiconductor substrate. For example, in the second semiconductor substrate, a process is used in which a region in which a plurality of through contacts is provided is removed by etching, an insulating film is embedded in the removal region, and the plurality of through contacts is formed in the insulating film.

For example, Patent Document 1 discloses a semiconductor device in which a connection portion is connected via a metal pad provided on a bonding surface between a first semiconductor component and a second semiconductor component.

### CITATION LIST

### Patent Document

Patent Document 1: Japanese Patent Application Laid-Open No. 2020-141397

### SUMMARY OF THE INVENTION

### Problems to be Solved by the Invention

By the way, as described above, in order to apply the process of embedding the insulating film in the removal region provided with the plurality of through contacts, it is necessary to secure a sufficient removal region in the second semiconductor substrate, and there is a concern that the effective area of the second semiconductor substrate is reduced. In a case where the effective area of the second semiconductor substrate is reduced, the number of pixel transistors that can be provided on the second semiconductor substrate is reduced, and as a result, it is difficult to improve the performance.

The present disclosure has been made in view of such a situation, and an object thereof is to achieve higher performance.

### Solutions to Problems

A solid-state imaging element according to one aspect of the present disclosure includes: a first semiconductor substrate provided with a photodiode and some pixel transistors for each pixel; a second semiconductor substrate bonded to the first semiconductor substrate and provided with another pixel transistor other than the some pixel transistors constituting the pixel; an interlayer film stacked on a surface of the second semiconductor substrate via an insulating film, the surface being opposite to a surface on a side to which the first semiconductor substrate is bonded; and a through electrode that penetrates the second semiconductor substrate from the interlayer film side and is electrically connected to the first semiconductor substrate, in which the through electrode includes a lower electrode provided from substantially the same height as a surface of the second semiconductor substrate on the interlayer film side toward the second semiconductor substrate, and an upper electrode penetrating the interlayer film and connected to the lower electrode.

A manufacturing method according to one aspect of the present disclosure includes: bonding a second semiconductor substrate to a first semiconductor substrate provided with a photodiode and some pixel transistors for each pixel, the second semiconductor substrate being provided with another pixel transistor other than the some pixel transistors constituting the pixel; stacking an interlayer film on a surface of the second semiconductor substrate via an insulating film, the surface being opposite to a surface on a side to which the first semiconductor substrate is bonded; and forming a through electrode that penetrates the second semiconductor substrate from the interlayer film side and is electrically connected to the first semiconductor substrate, in which the through electrode includes a lower electrode provided from substantially the same height as a surface of the second semiconductor substrate on the interlayer film side toward the second semiconductor substrate, and an upper electrode penetrating the interlayer film and connected to the lower electrode.

An electronic device according to one aspect of the present disclosure includes a solid-state imaging element, the solid-state imaging element including: a first semiconductor substrate provided with a photodiode and some pixel transistors for each pixel; a second semiconductor substrate bonded to the first semiconductor substrate and provided with another pixel transistor other than the some pixel transistors constituting the pixel; an interlayer film stacked on a surface of the second semiconductor substrate via an insulating film, the surface being opposite to a surface on a side to which the first semiconductor substrate is bonded; and a through electrode that penetrates the second semiconductor substrate from the interlayer film side and is electrically connected to the first semiconductor substrate, in which the through electrode includes a lower electrode provided from substantially the same height as a surface of the second semiconductor substrate on the interlayer film side toward the second semiconductor substrate, and an upper electrode penetrating the interlayer film and connected to the lower electrode.

In one aspect of the present disclosure, a second semiconductor substrate is bonded to a first semiconductor substrate provided with a photodiode and some pixel transistors for each pixel, the second semiconductor substrate being provided with pixel transistors other than the some pixel transistors constituting the pixel, an interlayer film is stacked on a surface of the second semiconductor substrate via an insulating film, the surface being opposite to a surface on a side to which the first semiconductor substrate is bonded, and a through electrode penetrating the second semiconductor substrate from the interlayer film side and electrically connected to the first semiconductor substrate is formed. Then, the through electrode includes a lower electrode provided from substantially the same height as the surface of the second semiconductor substrate on the interlayer film side toward the second semiconductor substrate, and an upper electrode penetrating the interlayer film and connected to the lower electrode.

### BRIEF DESCRIPTION OF DRAWINGS

FIG. 1 is a cross-sectional view illustrating a configuration example of a first embodiment of an imaging element to which the present technology is applied.

FIG. 2 is a diagram illustrating a method of manufacturing the imaging element.

FIG. 3 is a diagram illustrating a method of manufacturing the imaging element.

FIG. 4 is a cross-sectional view illustrating a configuration example of a second embodiment of the imaging element.

FIG. 5 is a cross-sectional view illustrating a configuration example of third and fourth embodiments of the imaging element.

FIG. 6 is a cross-sectional view illustrating a configuration example of a fifth embodiment of the imaging element.

FIG. 7 is a cross-sectional view illustrating a configuration example of a sixth embodiment of the imaging element.

FIG. 8 is a block diagram illustrating a configuration example of an imaging device.

FIG. 9 is a diagram illustrating a use example in which an image sensor is used.

### MODE FOR CARRYING OUT THE INVENTION

Hereinafter, a specific embodiment to which the present technology is applied is described in detail with reference to the drawings.

### <First Configuration Example of Imaging Element>

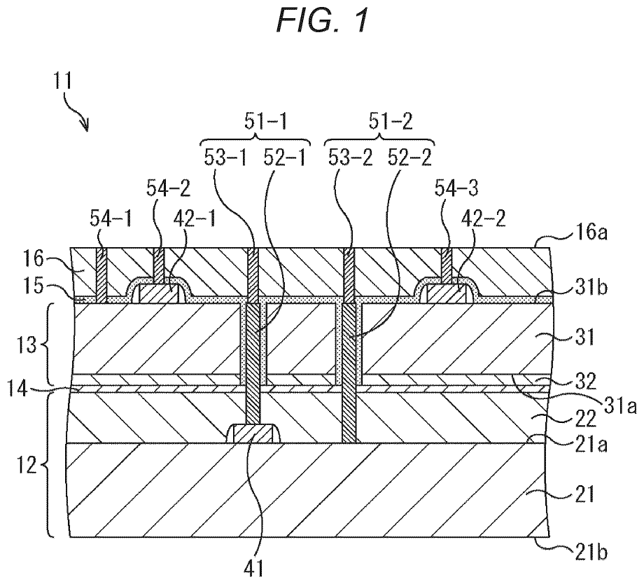

FIG. 1 is a diagram illustrating a cross-sectional configuration example of a first embodiment of an imaging element to which the present technology is applied.

An imaging element 11 illustrated in FIG. 1 is, for example, a back-illuminated CMOS image sensor having a stacked structure in which a logic substrate provided with a logic circuit for driving pixels is stacked on a sensor substrate provided with a plurality of pixels. For example, the sensor substrate of the imaging element 11 can adopt, for each pixel, a two-stage structure in which a first semiconductor substrate 12 provided with some elements (for example, a photodiode or a transfer transistor) constituting a pixel and a second semiconductor substrate 13 provided with some remaining elements (for example, an amplification transistor, a selection transistor, a reset transistor, and the like) constituting a pixel are bonded.

The imaging element 11 is configured by bonding the first semiconductor substrate 12 and the second semiconductor substrate 13 via a bonding layer 14, and stacking an insulating film 15 and an interlayer film 16 on the second semiconductor substrate 13.

The first semiconductor substrate 12 is configured by stacking an interlayer insulating film 22 including SiO₂ or the like on a front surface 21a of a semiconductor layer 21 including a silicon wafer or the like, for example. Furthermore, a plurality of photodiodes (not illustrated) is provided in the semiconductor layer 21 in an array, and the photodiodes are irradiated with light from a back surface 21b of the semiconductor layer 21.

The second semiconductor substrate 13 is configured by stacking an interlayer insulating film 32 including SiO₂ or the like on a front surface 31a of a semiconductor layer 31 including a silicon wafer or the like, for example. Then, the interlayer insulating film 32 of the second semiconductor substrate 13 is bonded to the interlayer insulating film 22 of the first semiconductor substrate 12.

Furthermore, in the imaging element 11, some pixel transistors 41 (for example, a transfer transistor) for driving pixels are provided on the front surface 21a of the semiconductor layer 21 of the first semiconductor substrate 12, and other pixel transistors 42-1 and 42-2 (for example, an amplification transistor, a selection transistor, a reset transistor, and the like) for driving pixels are provided on a back surface 31b of the semiconductor layer 31 of the second semiconductor substrate 13. Then, in the imaging element 11, in order to electrically connect the first semiconductor substrate 12 and the second semiconductor substrate 13, or in order to electrically connect the first semiconductor substrate 12 and a logic substrate (not illustrated), a through electrode 51 is provided so as to penetrate the second semiconductor substrate 13 and be connected to the first semiconductor substrate 12.

For example, the through electrode 51 includes a lower electrode 52 provided from the height of the back surface 31b of the second semiconductor substrate 13 toward the first semiconductor substrate 12, and an upper electrode 53 provided from the height of a front surface 16a of the interlayer film 16 to the height of the back surface 31b of the second semiconductor substrate 13. Note that the upper surface of the lower electrode 52 and the lower surface of the upper electrode 53 are only required to be substantially the same as the height of the back surface 31b of the second semiconductor substrate 13, and do not need to be strictly the same.

The through electrode 51-1 that supplies a drive signal to the pixel transistor 41 includes the lower electrode 52-1 provided so as to be connected to the pixel transistor 41 from the height of the back surface 31b of the second semiconductor substrate 13, and the upper electrode 53-1 provided so as to be connected to the lower electrode 52-1 from the front surface 16a of the interlayer film 16. The through electrode 51-2 that supplies the potential of the semiconductor layer 21 includes the lower electrode 52-2 provided so as to be connected to the front surface 21a of the semiconductor layer 21 from the height of the back surface 31b of the second semiconductor substrate 13, and the upper electrode 53-2 provided so as to be connected to the lower electrode 52-2 from the front surface 16a of the interlayer film 16.

Moreover, the interlayer film 16 is provided with an electrode 54 electrically connected to the second semiconductor substrate 13. For example, the electrode 54-1 that supplies the potential of the second semiconductor substrate 13, the electrode 54-2 that supplies a drive signal to the pixel transistor 42-1, and the electrode 54-3 that supplies a drive signal to the pixel transistor 42-2 are provided.

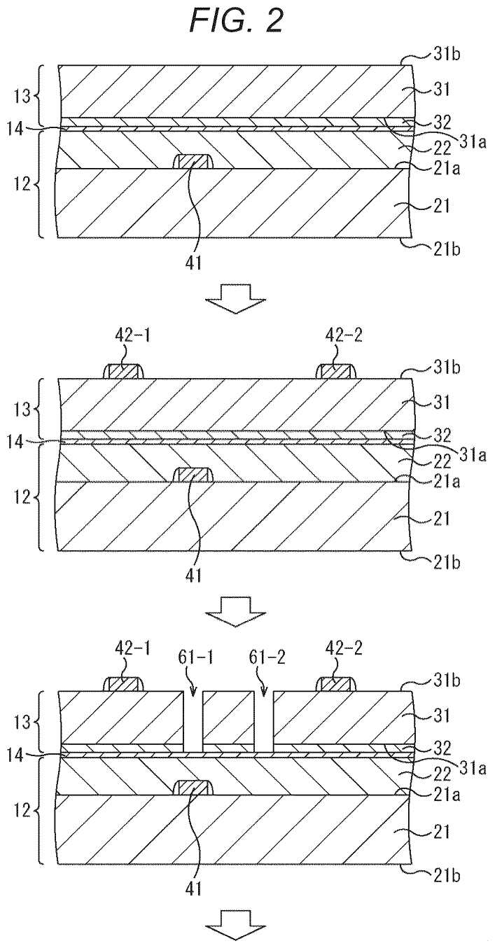

Then, in the imaging element 11, the diameter of a hole 61 (see FIG. 2) processed with respect to the second semiconductor substrate 13 in the step of forming the through electrode 51 is larger than the diameter of the lower electrode 52 penetrating the second semiconductor substrate 13, and the insulating film 15 is provided between the lower electrode 52 and the semiconductor layer 31 of the second semiconductor substrate 13. As a result, electrical insulation can be provided between the through electrode 51 and the semiconductor layer 31 of the second semiconductor substrate 13, and coupling capacitance between the through electrode 51 and the semiconductor layer 31 can be suppressed. Moreover, the coupling capacitance can be further reduced by using a low dielectric constant film for the insulating film 15.

Furthermore, as described above, in the conventional configuration in which the insulating film is embedded in a removal region where a plurality of the through electrodes 51 is provided, the effective area of the second semiconductor substrate 13 is reduced, and it is difficult to improve the performance. On the other hand, in the imaging element 11, since the area of the region required for providing the through electrode 51 can be reduced as compared with the conventional configuration, the effective area of the second semiconductor substrate 13 can be expanded as compared with the conventional configuration, and as a result, higher performance can be achieved.

Furthermore, since the conventional process is a process of collectively forming a through electrode from the front surface 16a of the interlayer film 16 to the first semiconductor substrate 12, the aspect ratio (a ratio of the diameter to the depth) of the through electrode is increased. On the other hand, in the imaging element 11, the aspect ratio of the through electrode 51 can be decreased by a process of forming the lower electrode 52 not from the front surface 16a of the interlayer film 16 but from the height of the back surface 31b of the second semiconductor substrate 13 to the first semiconductor substrate 12, and forming the upper electrode 53 from the front surface 16a of the interlayer film 16 to the lower electrode 52. As described above, by relaxing the aspect ratio of the through electrode 51, processing can be easily performed, and the diameter can be further reduced. Note that, as for the number of process steps as well, the process of forming the upper electrode 53 can be performed at the same time as the formation of the electrode 54, so that the through electrode 51 can be formed substantially in the same number of process steps as the conventional process.

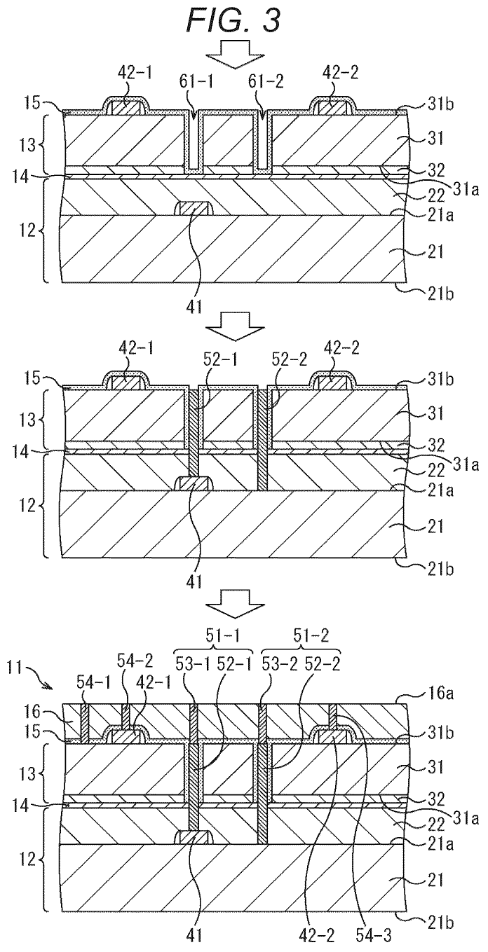

A method of manufacturing the imaging element 11 will be described with reference to FIGS. 2 and 3.

In the first step, as illustrated in the first stage of FIG. 2, after the second semiconductor substrate 13 is bonded to the first semiconductor substrate 12, thinning processing is performed on the back surface 31b side of the second semiconductor substrate 13.

In the second step, as illustrated in the second stage of FIG. 2, an element formation process of forming the pixel transistors 42-1 and 42-2 on the back surface 31b of the semiconductor layer 31 of the second semiconductor substrate 13 is performed.

In the third step, as illustrated in the third stage of FIG. 2, hole processing of forming the holes 61-1 and 61-2 by digging the second semiconductor substrate 13 is performed. Here, the holes 61-1 and 61-2 are formed until the bonding layer 14 is opened from the back surface 31b of the semiconductor layer 31 of the second semiconductor substrate 13.

In the fourth step, as illustrated in the first stage of FIG. 3, the insulating film 15 is formed. The insulating film 15 covers the back surface 31b of the semiconductor layer 31, the pixel transistors 42-1 and 42-2, and the like, and is provided along the inner peripheral surface and the bottom surface of the holes 61-1 and 61-2.

In the fifth step, the hole processing is performed until the bottom surface of the hole 61-1 is dug to open the pixel transistor 41 and until the bottom surface of the hole 61-2 is dug to open the front surface 21a of the semiconductor layer 21. Thereafter, by embedding a contact material in the holes 61-1 and 61-2, the lower electrodes 52-1 and 52-2 are formed as illustrated in the second stage of FIG. 3. For example, tungsten, a metal material such as copper, titanium, titanium nitride, tantalum, or ruthenium, or polysilicon doped with impurities is used as the contact material.

In the sixth step, as illustrated in the third stage of FIG. 3, the interlayer film 16 is stacked on the insulating film 15, and the upper electrode 53 and the electrode 54 are formed so as to penetrate the interlayer film 16. At this time, the upper electrode 53-1 is formed so as to be connected to the lower electrode 52-1 to constitute the through electrode 51-1, and the upper electrode 53-2 is formed so as to be connected to the lower electrode 52-2 to constitute the through electrode 51-2. Moreover, in the subsequent step, wiring and a metal pad (both not illustrated) are formed, wafer bonding is performed between the second semiconductor substrate 13 and the logic substrate using the metal pad, and the imaging element 11 having a stacked structure is formed by thinning the first semiconductor substrate 12.

Through the steps as described above, it is possible to manufacture the imaging element 11 in which the first semiconductor substrate 12 and the second semiconductor substrate 13 or the logic substrate are electrically connected by the through electrode 51, the through electrode 51 including the lower electrode 52 provided from the height of the back surface 31b of the second semiconductor substrate 13 toward the first semiconductor substrate 12 and the upper electrode 53 penetrating the interlayer film 16 and connected to the lower electrode 52.

Furthermore, by making the diameter of the lower electrode 52 larger than the diameter of the upper electrode 53, in the sixth step, the through electrode 51 can be formed such that the upper electrode 53 is more reliably connected to the lower electrode 52.

Alternatively, in a case where the lower electrode 52 has a contact stopper film, since a contact can be formed by self-aligned contact (SAC), the diameter of the lower electrode 52 may be smaller than the diameter of the upper electrode 53.

Note that the order of the steps of manufacturing the imaging element 11 may be changed, and the hole processing of forming the holes 61-1 and 61-2 may be performed before performing the element formation process of the pixel transistors 42-1 and 42-2. Then, after performing necessary thermal processing in the element formation process, hole processing of opening up to the pixel transistor 41 and the front surface 21a of the semiconductor layer 21 may be performed, and a contact material may be embedded to form the lower electrodes 52-1 and 52-2.

### <Second Configuration Example of Imaging Element>

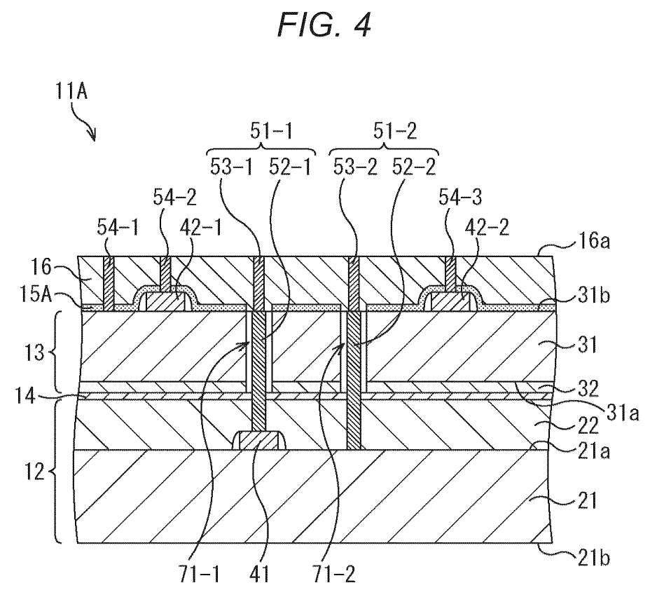

FIG. 4 is a diagram illustrating a cross-sectional configuration example of a second embodiment of the imaging element to which the present technology is applied. Note that, in the configuration of an imaging element 11A illustrated in FIG. 4, components common to those of the imaging element 11 in FIG. 1 are denoted by the same reference numerals, and a detailed description thereof will be omitted.

As illustrated in FIG. 4, in the imaging element 11A, similarly to the imaging element 11 in FIG. 1, the first semiconductor substrate 12 and the second semiconductor substrate 13 or the logic substrate are electrically connected by the through electrode 51 including the lower electrode 52 and the upper electrode 53. Then, the imaging element 11A has a configuration different from that of the imaging element 11 in FIG. 1 in that an air gap 71 is provided between the through electrode 51 and the semiconductor layer 31 of the second semiconductor substrate 13.

That is, in the imaging element 11 of FIG. 1, the insulating film 15 is provided between the through electrode 51 and the semiconductor layer 31 of the second semiconductor substrate 13, whereas in the imaging element 11A, the insulating film 15 between the through electrode 51 and the semiconductor layer 31 of the second semiconductor substrate 13 is removed. As described above, even if the air gap 71 is provided by removing the insulating film 15 (spacer) between the through electrode 51 and the semiconductor layer 31 of the second semiconductor substrate 13, the through electrode 51 can physically maintain its shape by the interlayer insulating film 22 between the semiconductor layer 21 and the semiconductor layer 31.

For example, after the through electrode 51 is formed by forming the insulating film 15, the insulating film 15 between the through electrode 51 and the semiconductor layer 31 of the second semiconductor substrate 13 can be removed by a limited wet etching or dry etching process. Alternatively, the insulating film 15 may be removed using lithography.

As described above, in the imaging element 11A, the coupling capacitance can be further reduced by providing the air gap 71 between the through electrode 51 and the semiconductor layer 31 of the second semiconductor substrate 13.

### <Third and Fourth Configuration Examples of Imaging Element>

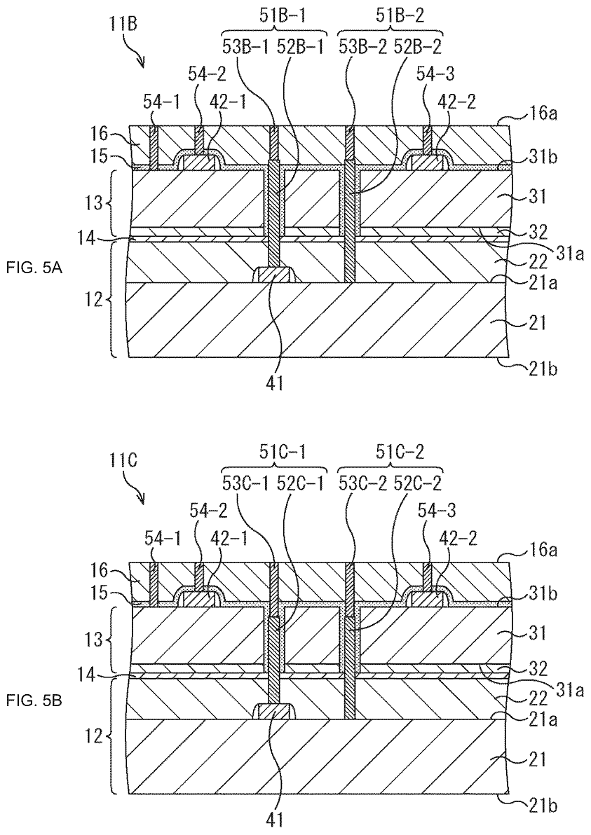

FIG. 5 is a diagram illustrating a cross-sectional configuration example of third and fourth embodiments of the imaging element to which the present technology is applied. Note that, in the configuration of imaging elements 11B and 11C illustrated in FIG. 5, components common to those of the imaging element 11 in FIG. 1 are denoted by the same reference numerals, and a detailed description thereof will be omitted.

As illustrated in A of FIG. 5, in the imaging element 11B, similarly to the imaging element 11 in FIG. 1, the first semiconductor substrate 12 and the second semiconductor substrate 13 or the logic substrate are electrically connected by a through electrode 51B including a lower electrode 52B and an upper electrode 53B. Then, the imaging element 11B has a configuration different from that of the imaging element 11 in FIG. 1 in that the through electrode 51B is configured in a shape in which the upper surface of the lower electrode 52B and the lower surface of the upper electrode 53B are higher than the height of the back surface 31b of the semiconductor layer 31 of the second semiconductor substrate 13. That is, in the imaging element 11B, the lower electrode 52B is formed so as to be convex with respect to the back surface 31b of the semiconductor layer 31 of the second semiconductor substrate 13. Note that the height of the lower electrode 52B is preferably lower than that of the gate electrode of the pixel transistor 42.

As illustrated in B of FIG. 5, in the imaging element 11C, similarly to the imaging element 11 in FIG. 1, the first semiconductor substrate 12 and the second semiconductor substrate 13 or the logic substrate are electrically connected by a through electrode 51C including a lower electrode 52C and an upper electrode 53C. Then, the imaging element 11C has a configuration different from that of the imaging element 11 in FIG. 1 in that the through electrode 51C is configured in a shape in which the upper surface of the lower electrode 52C and the lower surface of the upper electrode 53C are lower than the height of the back surface 31b of the semiconductor layer 31 of the second semiconductor substrate 13. That is, in the imaging element 11C, the lower electrode 52C is formed so as to be recessed with respect to the back surface 31b of the semiconductor layer 31 of the second semiconductor substrate 13.

As described above, the lower electrode 52B may be convex with respect to the back surface 31b of the semiconductor layer 31 of the second semiconductor substrate 13, or the lower electrode 52C may be recessed with respect to the back surface 31b of the semiconductor layer 31 of the second semiconductor substrate 13, and the heights of the lower electrodes 52B and 52C may not be the same as the height of the back surface 31b of the second semiconductor substrate 13.

### <Fifth Configuration Example of Imaging Element>

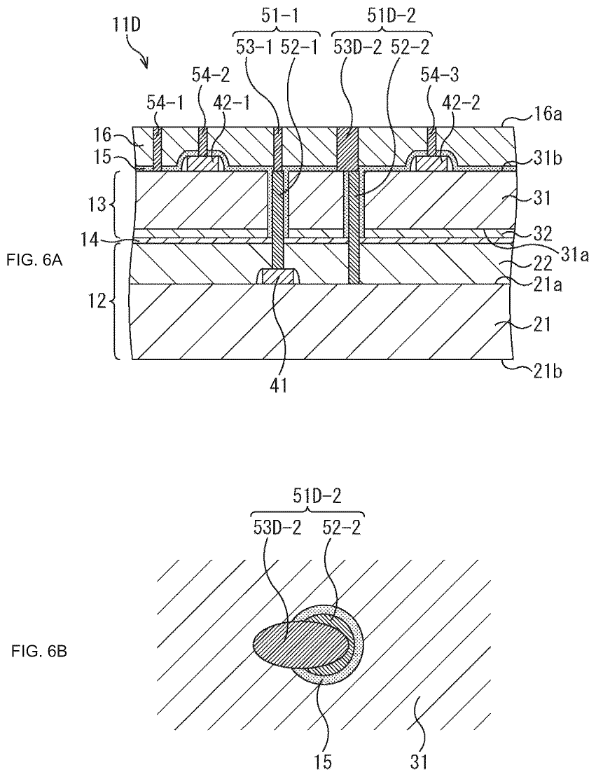

FIG. 6 is a diagram illustrating a cross-sectional configuration example of a fifth embodiment of the imaging element to which the present technology is applied. Note that, in the configuration of an imaging element 11D illustrated in FIG. 6, components common to those of the imaging element 11 in FIG. 1 are denoted by the same reference numerals, and a detailed description thereof will be omitted.

A of FIG. 6 illustrates a cross-sectional configuration example of the imaging element 11D, and B of FIG. 6 illustrates a planar configuration example in the vicinity of a through electrode 51D-2.

As illustrated in B of FIG. 6, the imaging element 11D has a configuration different from the imaging element 11 of FIG. 1 in that the shape of an upper electrode 53D-2 constituting the through electrode 51D-2 that supplies the potential of the semiconductor layer 21 is elliptical in a plan view, and as illustrated in A of FIG. 6, the upper electrode 53D-2 is also connected to the back surface 31b of the semiconductor layer 31 of the second semiconductor substrate 13. Note that the present structure is limited to a case where the first semiconductor substrate 12 and the second semiconductor substrate 13 are electrically at the same potential.

That is, in the imaging element 11D, in a case where the semiconductor layer 21 of the first semiconductor substrate 12 and the semiconductor layer 31 of the second semiconductor substrate 13 are at the same potential, the through electrode 51D-2 is connected to both the semiconductor layer 21 and the semiconductor layer 31, and the through electrode 51D-2 can be used so as to supply a potential to both the semiconductor layer 21 and the semiconductor layer 31.

As described above, the imaging element 11D can have a configuration in which the upper electrode 53D-2 is also connected to the semiconductor layer 31 together with the lower electrode 52-2 by forming the upper electrode 53D-2 in an elliptical shape. Note that, in the configuration example described with reference to FIG. 6, the shape of the upper electrode 53D-2 is elliptical. However, as long as the lower electrode 52-2 and the semiconductor layer 31 can be connected, the shape of the upper electrode 53D-2 is not limited to the elliptical shape, and other shapes may be adopted.

### <Sixth Configuration Example of Imaging Element>

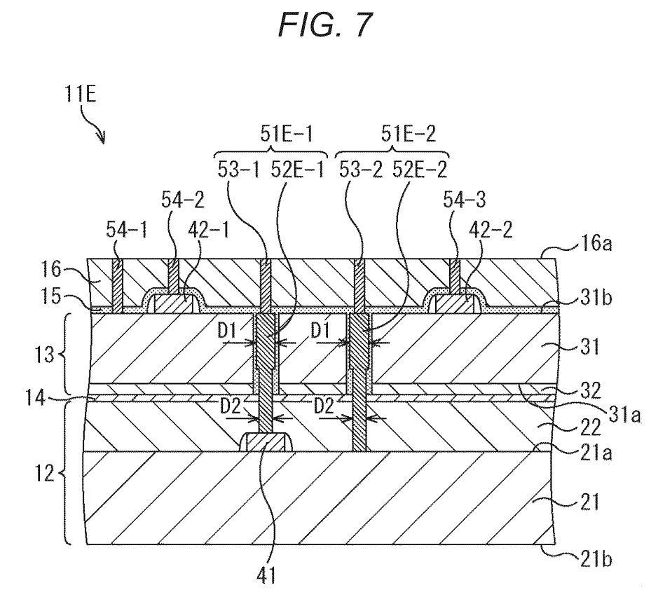

FIG. 7 is a diagram illustrating a cross-sectional configuration example of a sixth embodiment of the imaging element to which the present technology is applied. Note that, in the configuration of an imaging element 11E illustrated in FIG. 7, components common to those of the imaging element 11 in FIG. 1 are denoted by the same reference numerals, and a detailed description thereof will be omitted.

As illustrated in FIG. 7, in the imaging element 11E, similarly to the imaging element 11 in FIG. 1, the first semiconductor substrate 12 and the second semiconductor substrate 13 or the logic substrate are electrically connected by a through electrode 51E including a lower electrode 52E and the upper electrode 53. Then, in the imaging element 11E, in a case where the lower electrode 52E cannot be collectively formed due to the influence of silicon, a junction film in the middle, or the like, for example, depending on the processing process, the lower electrode 52E can be configured in a staircase shape. For example, in the illustrated example, the through electrode 51E includes the lower electrode 52E having a two-step shape and having a large diameter D1 on the upper side and a small diameter D2 on the lower side.

As described above, the imaging element 11E may be formed such that the diameter of at least a part of the lower electrode 52E is different from the diameter of another part of the lower electrode 52E depending on the processing process.

### <Configuration Example of Electronic Device>

The imaging element 11 described above may be applied to various electronic devices such as an imaging system such as a digital still camera and a digital video camera, a mobile phone having an imaging function, or another device having an imaging function, for example.

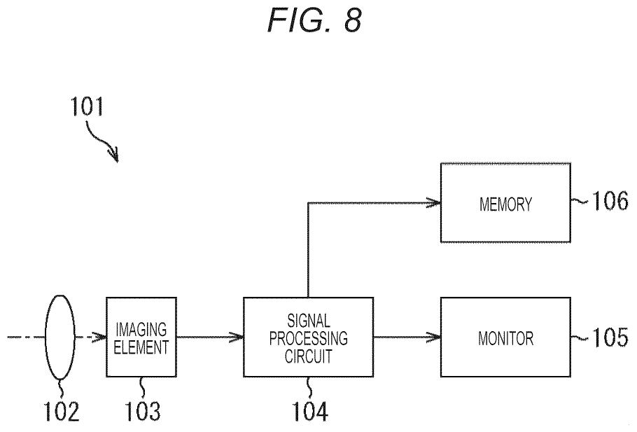

FIG. 8 is a block diagram illustrating a configuration example of an imaging device mounted on an electronic device.

As illustrated in FIG. 8, an imaging device 101 includes an optical system 102, an imaging element 103, a signal processing circuit 104, a monitor 105, and a memory 106, and can capture a still image and a moving image.

The optical system 102 includes one or a plurality of lenses, guides image light (incident light) from a subject to the imaging element 103, and forms an image on a light-receiving surface (sensor unit) of the imaging element 103.

As the imaging element 103, the imaging element 11 described above is applied. Electrons are accumulated in the imaging element 103 for a certain period in accordance with the image formed on the light-receiving surface through the optical system 102. Then, a signal corresponding to the electrons accumulated in the imaging element 103 is supplied to the signal processing circuit 104.

The signal processing circuit 104 performs various types of signal processing on a pixel signal output from the imaging element 103. An image (image data) obtained by the signal processing performed by the signal processing circuit 104 is supplied to the monitor 105 to be displayed or supplied to the memory 106 to be stored (recorded).

In the imaging device 101 configured as described above, for example, a better image can be captured by applying the above-described imaging element 11.

### <Use Examples of Image Sensor>

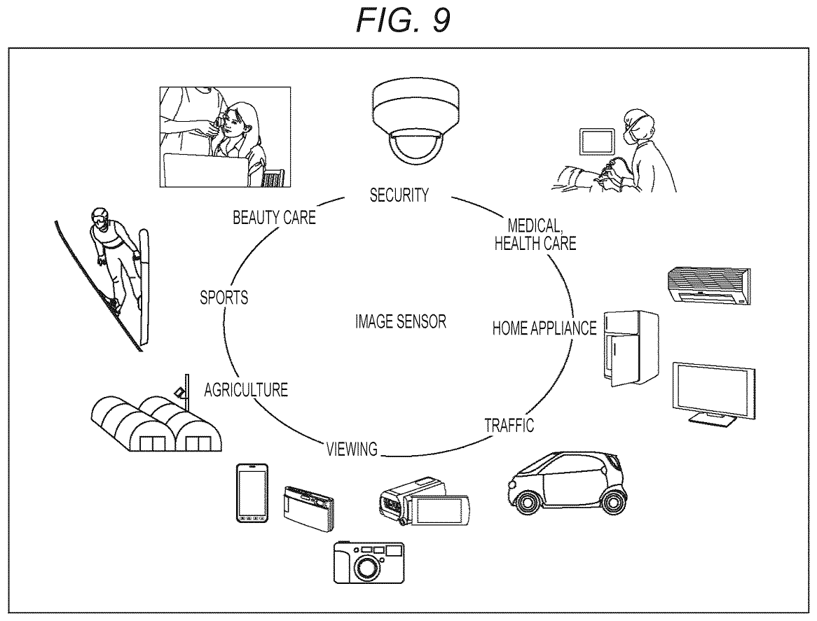

FIG. 9 is a diagram illustrating a use example of the above-described image sensor (imaging element).

The image sensor described above can be used in various cases for sensing light such as visible light, infrared light, ultraviolet light, and X-ray as described below, for example.
A device that captures an image to be used for viewing, such as a digital camera and a portable device with a camera function
A device for traffic purpose, such as an in-vehicle sensor that captures images of the front, rear, surroundings, interior and the like of an automobile for safe driving such as automatic stop, recognition of a driver's condition, and the like, a surveillance camera that monitors traveling vehicles and roads, and a ranging sensor that measures a distance between vehicles and the like.
A device used for home appliance such as a TV, a refrigerator, and an air conditioner to image a user's gesture and perform device operation according to the gesture.
A device used for medical and health care such as an endoscope and a device that performs angiography by receiving infrared light.
A device used for security such as a security monitoring camera and an individual authentication camera
A device used for beauty care, such as a skin measuring instrument for imaging skin, and a microscope for imaging scalp
A device used for sports, such as an action camera or a wearable camera for sports applications or the like
A device used for agricultural purpose such as a camera for monitoring a condition of fields and crops

### Combination Examples of Configurations

Note that the present technology can also have the following configurations.

(1)

A solid-state imaging element including:
a first semiconductor substrate provided with a photodiode and some pixel transistors for each pixel;
a second semiconductor substrate bonded to the first semiconductor substrate and provided with another pixel transistor other than the some pixel transistors constituting the pixel;
an interlayer film stacked on a surface of the second semiconductor substrate via an insulating film, the surface being opposite to a surface on a side to which the first semiconductor substrate is bonded; and
a through electrode that penetrates the second semiconductor substrate from the interlayer film side and is electrically connected to the first semiconductor substrate,
in which the through electrode includes a lower electrode provided from substantially the same height as a surface of the second semiconductor substrate on the interlayer film side toward the second semiconductor substrate, and an upper electrode penetrating the interlayer film and connected to the lower electrode.
   (2)

The solid-state imaging element according to (1),
in which an insulating layer is provided between the lower electrode and the second semiconductor substrate.
   (3)

The solid-state imaging element according to (1),
in which an interlayer insulating film is provided between the semiconductor layer of the first semiconductor substrate and the semiconductor layer of the second semiconductor substrate and a part of the lower electrode is held by the interlayer insulating film, and
an air gap is provided between the lower electrode and the second semiconductor substrate.
   (4)

The solid-state imaging element according to any one of (1) to (3),
in which a diameter of the lower electrode is larger than a diameter of the upper electrode.
   (5)

The solid-state imaging element according to any one of (1) to (4),
in which the lower electrode has a shape in which an upper surface of the lower electrode is higher than a height of a surface of the second semiconductor substrate on the interlayer film side and lower than a gate electrode of an element provided on the second semiconductor substrate.
   (6)

The solid-state imaging element according to any one of (1) to (4),
in which the lower electrode has a shape in which an upper surface of the lower electrode is lower than a height of a surface of the second semiconductor substrate on the interlayer film side.
   (7)

The solid-state imaging element according to any one of (1) to (6),
in which in a case where the first semiconductor substrate and the second semiconductor substrate are at the same potential, the upper electrode constituting the through electrode is configured in a shape connected also to the second semiconductor substrate, the through electrode supplying a potential to the first semiconductor substrate and the second semiconductor substrate.
   (8)

The solid-state imaging element according to any one of (1) to (7),
in which the lower electrode is configured in a staircase shape in which at least a part of a diameter is different from a diameter of another part.
   (9)

A method of manufacturing a solid-state imaging element, the method including:
bonding a second semiconductor substrate to a first semiconductor substrate provided with a photodiode and some pixel transistors for each pixel, the second semiconductor substrate being provided with another pixel transistor other than the some pixel transistors constituting the pixel;
stacking an interlayer film on a surface of the second semiconductor substrate via an insulating film, the surface being opposite to a surface on a side to which the first semiconductor substrate is bonded; and
forming a through electrode that penetrates the second semiconductor substrate from the interlayer film side and is electrically connected to the first semiconductor substrate,
in which the through electrode includes a lower electrode provided from substantially the same height as a surface of the second semiconductor substrate on the interlayer film side toward the second semiconductor substrate, and an upper electrode penetrating the interlayer film and connected to the lower electrode.
   (10)

An electronic device including a solid-state imaging element, the solid-state imaging element including:
a first semiconductor substrate provided with a photodiode and some pixel transistors for each pixel;
a second semiconductor substrate bonded to the first semiconductor substrate and provided with another pixel transistor other than the some pixel transistors constituting the pixel;
an interlayer film stacked on a surface of the second semiconductor substrate via an insulating film, the surface being opposite to a surface on a side to which the first semiconductor substrate is bonded; and
a through electrode that penetrates the second semiconductor substrate from the interlayer film side and is electrically connected to the first semiconductor substrate,
in which the through electrode includes a lower electrode provided from substantially the same height as a surface of the second semiconductor substrate on the interlayer film side toward the second semiconductor substrate, and an upper electrode penetrating the interlayer film and connected to the lower electrode.

Note that, the present embodiment is not limited to the embodiment described above, and various modifications can be made without departing from the gist of the present disclosure. Furthermore, the effects described in the present description are merely examples and are not limited, and other effects may be provided.

### REFERENCE SIGNS LIST

11 Imaging element
12 First semiconductor substrate
13 Second semiconductor substrate
14 Bonding layer
15 Insulating film
16 Interlayer film
21 Semiconductor layer
22 Interlayer insulating film
31 Semiconductor layer
32 Interlayer insulating film
41 and 42 Pixel transistor
51 Through electrode
52 Lower electrode
53 Upper electrode
54 Electrode
61 Hole
71 and 72 Air gap

1. A solid-state imaging element comprising:
a first semiconductor substrate provided with a photodiode and some pixel transistors for each pixel;
a second semiconductor substrate bonded to the first semiconductor substrate and provided with another pixel transistor other than the some pixel transistors constituting the pixel;
an interlayer film stacked on a surface of the second semiconductor substrate via an insulating film, the surface being opposite to a surface on a side to which the first semiconductor substrate is bonded; and
a through electrode that penetrates the second semiconductor substrate from the interlayer film side and is electrically connected to the first semiconductor substrate,
wherein the through electrode includes a lower electrode provided from substantially the same height as a surface of the second semiconductor substrate on the interlayer film side toward the second semiconductor substrate, and an upper electrode penetrating the interlayer film and connected to the lower electrode.

2. The solid-state imaging element according to claim 1,
wherein an insulating layer is provided between the lower electrode and the second semiconductor substrate.

3. The solid-state imaging element according to claim 1,
wherein an interlayer insulating film is provided between the semiconductor layer of the first semiconductor substrate and the semiconductor layer of the second semiconductor substrate and a part of the lower electrode is held by the interlayer insulating film, and
an air gap is provided between the lower electrode and the second semiconductor substrate.

4. The solid-state imaging element according to claim 1,
wherein a diameter of the lower electrode is larger than a diameter of the upper electrode.

5. The solid-state imaging element according to claim 1,
wherein the lower electrode has a shape in which an upper surface of the lower electrode is higher than a height of a surface of the second semiconductor substrate on the interlayer film side and lower than a gate electrode of an element provided on the second semiconductor substrate.

6. The solid-state imaging element according to claim 1,
wherein the lower electrode has a shape in which an upper surface of the lower electrode is lower than a height of a surface of the second semiconductor substrate on the interlayer film side.

7. The solid-state imaging element according to claim 1,
wherein in a case where the first semiconductor substrate and the second semiconductor substrate are at the same potential, the upper electrode constituting the through electrode is configured in a shape connected also to the second semiconductor substrate, the through electrode supplying a potential to the first semiconductor substrate and the second semiconductor substrate.

8. The solid-state imaging element according to claim 1,
wherein the lower electrode is configured in a staircase shape in which at least a part of a diameter is different from a diameter of another part.

9. A method of manufacturing a solid-state imaging element, the method comprising:
bonding a second semiconductor substrate to a first semiconductor substrate provided with a photodiode and some pixel transistors for each pixel, the second semiconductor substrate being provided with another pixel transistor other than the some pixel transistors constituting the pixel;
stacking an interlayer film on a surface of the second semiconductor substrate via an insulating film, the surface being opposite to a surface on a side to which the first semiconductor substrate is bonded; and
forming a through electrode that penetrates the second semiconductor substrate from the interlayer film side and is electrically connected to the first semiconductor substrate,
wherein the through electrode includes a lower electrode provided from substantially the same height as a surface of the second semiconductor substrate on the interlayer film side toward the second semiconductor substrate, and an upper electrode penetrating the interlayer film and connected to the lower electrode.

10. An electronic device including a solid-state imaging element, the solid-state imaging element comprising:
a first semiconductor substrate provided with a photodiode and some pixel transistors for each pixel;
a second semiconductor substrate bonded to the first semiconductor substrate and provided with another pixel transistor other than the some pixel transistors constituting the pixel;
an interlayer film stacked on a surface of the second semiconductor substrate via an insulating film, the surface being opposite to a surface on a side to which the first semiconductor substrate is bonded; and
a through electrode that penetrates the second semiconductor substrate from the interlayer film side and is electrically connected to the first semiconductor substrate,
wherein the through electrode includes a lower electrode provided from substantially the same height as a surface of the second semiconductor substrate on the interlayer film side toward the second semiconductor substrate, and an upper electrode penetrating the interlayer film and connected to the lower electrode.
